(19) United States
(12) Patent Application Publication
(10) Pub. No.: US 2002/0180047 A1
(43) Pub. Date: Dec. 5, 2002

(54) Method of fabricating a semiconductor device

(75) Inventors: Hideyo Haruhana, Tokyo (JP); Keiichi Higashitani, Tokyo (JP); Hiroyuki Amishiro, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: MITSUBISHI DENKI KABUSHIKI KAISHA, Tokyo (JP)

(21) Appl. No.: 10/195,063

(22) Filed: Jul. 15, 2002

Related U.S. Application Data
(62) Division of application No. 09/851,095, filed on May 9, 2001.

(30) Foreign Application Priority Data
Dec. 26, 2000 (JP) 2000-395942

(51) Int. Cl. H01L 21/302

(52) U.S. Cl. 257/756

(57) ABSTRACT

A method of fabricating a semiconductor device includes following four steps. (1) Cu wiring is buried in an insulating interlayer film, an insulating film for preventing diffusion of copper is deposited on a planarized surface including the Cu wiring as the uppermost layer, and another insulating film having high moisture resistance is deposited. (2) On the insulating film, a photosensitive polyimide material is applied, exposed, and developed, thereby forming an etching mask. (3) The etching mask is cured. (4) By using the cured etching mask, the insulating films are etched to expose the Cu wiring as the uppermost layer.

### FIELD OF THE INVENTION

The present invention in general relates to a semiconductor device using a copper wiring in the uppermost layer of a multilevel wiring and a method of fabricating such a semiconductor device. More particularly, this invention relates to a semiconductor device in which a passivation layer adapted to a copper wiring is formed on the surface including the copper wiring in the uppermost layer and also relates to a method of fabricating such a semiconductor device.

### BACKGROUND OF THE INVENTION

Conventionally, aluminum wiring (“Al wiring”) is used as a multilevel wiring of a semiconductor device. However, these days, in order to accomplish reduction in size and increase the processing speed of a semiconductor device, copper wiring (“Cu wiring”) is becoming popular. Copper wiring burying technique (Cu Damascene technique) is actively being studied and developed.

FIG. 9A to FIG. 9E are diagrams showing a process of formation of a passivation film in a conventional semiconductor device using Al wiring as a multilevel wiring. As shown in FIG. 9A, multilevel wiring comprises Al wiring 103 which is formed above an insulating interlayer film 101. The Al wiring 103 is formed by forming an Al film on the insulating interlayer film 101 via a barrier metal 102 and performing photolithography and etching on the Al film. After that, a passivation film 104 is formed so as to cover the Al wiring 103.

A polyimide material 105 is applied on the surface of the passivation film 104, exposed, and developed, thereby forming an etching mask as shown in FIG. 9B. After that, as shown in FIG. 9C, the passivation film 104 on the Al wiring 103 is removed by etching. Since the surface of a polyimide material 105 becomes a polyimide altered layer 105a due to the etching, as shown in FIG. 9D, the polyimide altered layer 105a is removed to expose the Al wiring 103 as the uppermost layer. Finally, as shown in FIG. 9E, the polyimide material 105 is cured.

When using Cu wiring as the uppermost layer of the multilevel wiring, in the step of removing the polyimide altered layer 105a as the surface of the polyimide material 105 shown in FIG. 9D and the step of curing the polyimide material 105 shown in FIG. 9E, the temperature becomes as high as 100 degree centigrade or higher in an atmosphere where oxygen exists. It causes a problem such that the surface of copper in the exposed portion is oxidized.

According to the conditions of forming the passivation film 104, there is a problem such that copper in the Cu wiring diffuses to a neighboring oxide film or the surface of copper is altered.

### SUMMARY OF THE INVENTION

It is an object of this invention to provide a semiconductor device in which oxidation of the surface of copper, diffusion of copper to a neighboring oxide film, or alternation of the surface of copper can be prevented at the time of forming a passivation portion of the semiconductor device using a Cu wiring as a multilevel wiring. It is also an object of this invention to provide a method of fabricating such a semiconductor device.

In the semiconductor device according to one aspect of this invention, a passivation layer is formed on a copper wiring as an uppermost layer. This passivation layer includes a first insulating film covering a planarized surface including the copper wiring as the uppermost layer, for preventing diffusion of copper or having high adhesion to copper; and a second insulating film formed on the first insulating film, having high moisture resistance or low dielectric constant.

According to the above-mentioned aspect, the first insulating film covers the planarized surface including the copper wiring as the uppermost layer, and prevents diffusion of copper or has high adhesion to copper. The second insulating film having high moisture resistance or low dielectric constant is formed on the first insulating film.

The method of fabricating a semiconductor device according to another aspect of this invention includes a copper wiring burying step of burying a copper wiring in an insulating interlayer film; a first insulating film forming step of depositing a first insulating film which prevents diffusion of copper or has high adhesion to copper on a planarized surface including the copper wiring as an uppermost layer; a second insulating film forming step of depositing a second insulating film having high moisture resistance or low dielectric constant on the first insulating film; an etching mask forming step of forming an etching mask by applying, exposing, and developing a photosensitive polyimide material on the second insulating film; a curing step of curing the etching mask; and an etching step of etching the second insulating film and the first insulating film by using the etching mask cured in the curing step to expose the copper wiring as the uppermost layer.

According to the above-mentioned aspect, a copper wiring is buried in an insulating interlayer film in the copper wiring burying step. In the first insulating film forming step, a first insulating film which prevents diffusion of copper or has high adhesion to copper is deposited on a planarized surface including the copper wiring as an uppermost layer. In the second insulating film forming step, a second insulating film having high moisture resistance or low dielectric constant is deposited on the first insulating film. In the etching mask forming step, an etching mask is formed by applying, exposing, and developing a photosensitive polyimide material on the second insulating film. In the curing step, the etching mask is cured. In the etching step, the second insulating film and the first insulating film are etched by using the etching mask cured in the curing step to expose the copper wiring as the uppermost layer. The diffusion of copper to the insulating film adjacent to the copper wiring is suppressed or adhesion of the insulating film to the copper wiring is increased by the first insulating film. Moisture resistance is enhanced or the dielectric is lowered by the second insulating film.

The method of fabricating a semiconductor device according to still another aspect of this invention includes a copper wiring burying step of burying a copper wiring in an insulating interlayer film; a passivation film forming step of depositing a passivation film on a planarized surface including the copper wiring as an uppermost layer; an etching mask forming step of forming an etching mask by applying, exposing, and developing a photosensitive polyimide material on the passivation film; a curing step of curing the etching mask; a first etching step of etching the passivation film to a predetermined thickness by using the etching mask cured in the first curing step; an altered layer removing step of removing an altered layer generated on the surface of the etching mask in the first etching step; and a second etching step of etching the passivation film having the predetermined thickness to expose the copper wiring as the uppermost layer.

According to the above-mentioned aspect, in the copper wiring burying step, a copper wiring is buried in an insulating interlayer film. In a passivation film forming step, a passivation film is deposited on a planarized surface including the copper wiring as an uppermost layer. In the etching mask forming step, an etching mask is formed by applying, exposing, and developing a photosensitive polyimide material on the passivation film. In the curing step, the etching mask is cured. In the first etching step, the passivation film is etched to a predetermined thickness by using the etching mask cured in the first curing step. In the altered layer removing step, an altered layer generated on the surface of the etching mask in the first etching step is removed. In the second etching step, the passivation film having the predetermined thickness is etched to expose the copper wiring as the uppermost layer. In such a manner, the final thickness of the polyimide altered layer is made thin.

The method of fabricating a semiconductor device according to still another aspect of this invention includes a copper wiring burying step of burying a copper wiring in an insulating interlayer film; a passivation film forming step of depositing a passivation film on a planarized surface including the copper wiring as an uppermost layer; an etching mask forming step of forming an etching mask by applying, exposing, and developing a photosensitive polyimide material on the passivation film; a first etching step of etching the passivation film to a predetermined thickness by using the etching mask formed in the etching mask forming step; an altered layer removing step of removing an altered layer generated on the surface of the etching mask in the first etching step; a curing step of curing the etching mask; and a second etching step of etching the passivation film having the predetermined thickness to expose the copper wiring as the uppermost layer.

According to the above-mentioned aspect, in the copper wiring burying step, a copper wiring is buried in an insulating interlayer film. In the passivation film forming step, a passivation film is deposited on a planarized surface including the copper wiring as an uppermost layer. In the etching mask forming step, an etching mask is formed by applying, exposing, and developing a photosensitive polyimide material on the passivation film. In the first etching step, the passivation film is etched to a predetermined thickness by using the etching mask formed in the etching mask forming step. In the altered layer removing step, an altered layer generated on the surface of the etching mask in the first etching step is removed. In the curing step, the etching mask is cured. In the second etching step, the passivation film having the predetermined thickness is etched to expose the copper wiring as the uppermost layer. The shape in the upper part of the passivation film etched before the curing process becomes the shape of the opening of the copper wiring, thereby increasing the dimensional accuracy of the passivation of the copper wiring.

In the above-mentioned aspects, it is preferable that the passivation film forming step includes a first insulating film forming step of depositing a first insulating film on a planarized surface including a copper wiring as an uppermost layer; and a second insulating film forming step of depositing a second insulating film having an etch selectivity different from that of the first insulating film on the first insulating film, in the first etching step, the second insulating film formed in the second insulating film forming step is etched by using the etching mask formed in the etching mask forming step, and in the second etching step, the second insulating film formed in the first insulating film forming step is etched.

According to the above-mentioned aspect, in the passivation film forming step, a first insulating film is deposited on a planarized surface including a copper wiring as an uppermost layer in the first insulating film forming step, and a second insulating film having an etch selectivity different from that of the first insulating film is deposited on the first insulating film in the second insulating film forming step. In the first etching step, the second insulating film formed in the second insulating film forming step is etched by using the etching mask formed in the etching mask forming step. In the second etching step, the second insulating film formed in the first insulating film forming step is etched.

Other objects and features of this invention will become apparent from the following description with reference to the accompanying drawings.

### BRIEF DESCRIPTION OF THE DRAWINGS

FIG. 1A to FIG. 1D are process drawings showing a method of fabricating a semiconductor device as a first embodiment of the invention;

FIG. 2A to FIG. 2D are process drawings showing a method of fabricating a semiconductor device as a second embodiment of the invention;

FIG. 3A to FIG. 3C are process drawings showing a method of fabricating a semiconductor device as a third embodiment of the invention;

FIG. 4A and FIG. 4B are process drawings showing the method according to the third embodiment after the step shown in FIG. 3C;

FIG. 5A to FIG. 5C are process drawings showing a method of fabricating a semiconductor device as a fourth embodiment of the invention;

FIG. 6A and FIG. 6B are process drawings showing the method according to the fourth embodiment after the step shown in FIG. 5C;

FIG. 7A to FIG. 7C are process drawings showing a method of fabricating a semiconductor device as a fifth embodiment of the invention;

FIG. 8A and FIG. 8B are process drawings showing the method according to the fifth embodiment after the step shown in FIG. 7C; and

FIG. 9A to FIG. 9E show process drawings showing a conventional method of fabricating a semiconductor device.

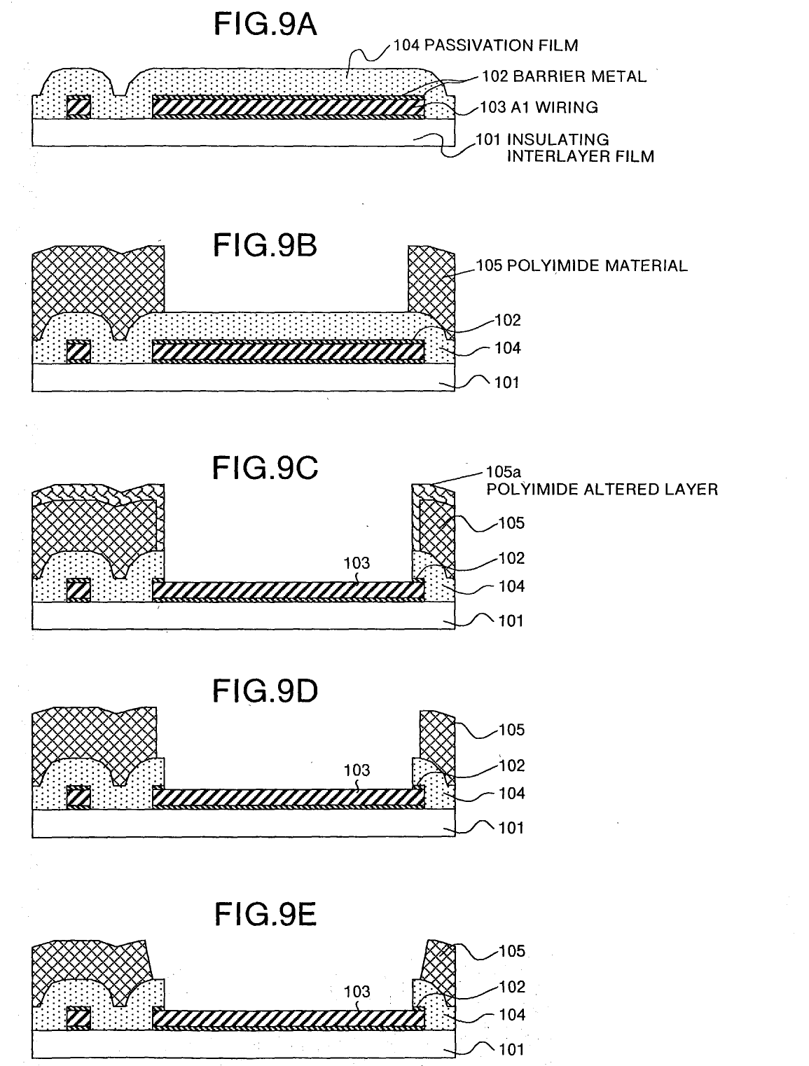

### DESCRIPTION OF THE PREFERRED EMBODIMENTS

Preferred embodiments of the semiconductor device and a method of fabricating the semiconductor device according to this invention will be described in detail hereinbelow with reference to the accompanying drawings.

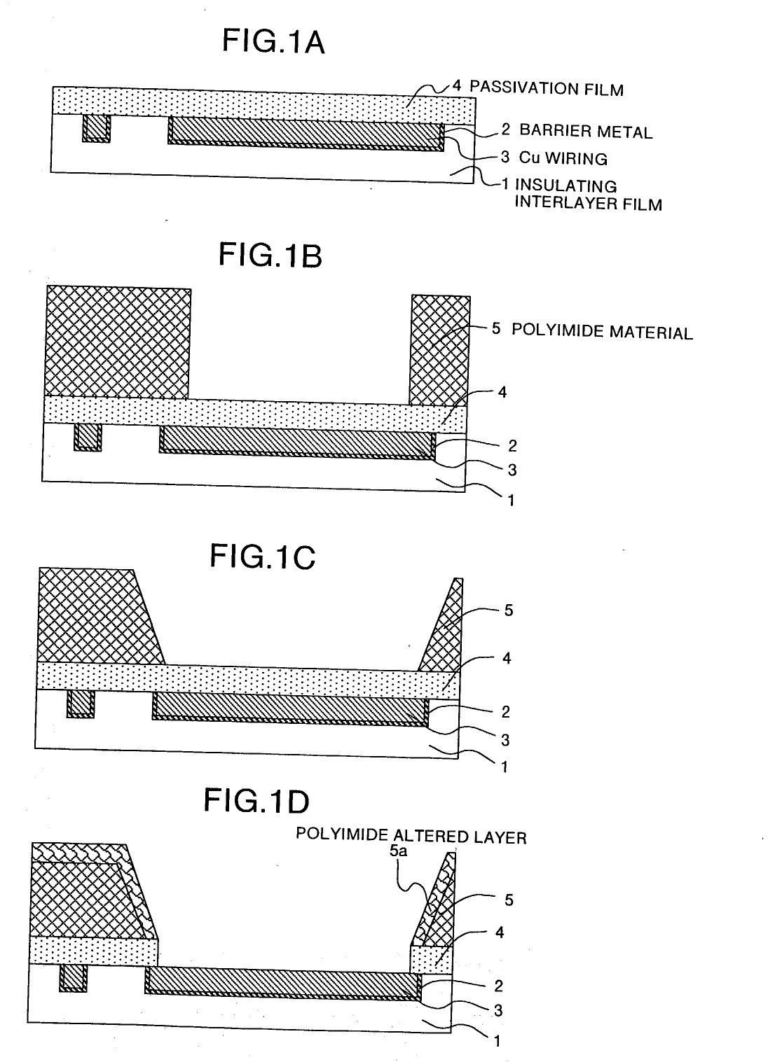

FIG. 1A to FIG. 1D are process drawings showing a method of fabricating a semiconductor device as a first embodiment of the invention. First, as shown in FIG. 1A, by using the Cu Damascene technique, a Cu wiring 3 having a planarized surface and obtained by burying copper in an insulating interlayer film 1 is formed. A passivation film 4 is deposited on the planarized surface including the Cu wiring 3. The passivation film 4 is a silicon nitride film.

Further, as shown in FIG. 1B, a photosensitive polyimide material 5 is applied on the passivation film 4, exposed, and developed, thereby forming an etching mask made of the polyimide material 5.

After curing the polyimide material 5 as shown in FIG. 1C, as shown in FIG. 1D, by using the polyimide material 5 as an etching mask, the passivation film 4 is etched. At this time, the surface of the polyimide material 5 become a polyimide altered layer 5a.

In this case, after curing the polyimide material 5 (FIG. 1C), the passivation film 4 is etched. Consequently, when copper in the Cu wiring 3 is exposed and in an atmosphere where oxygen exists, the temperature does not rise above 100 degree centigrade. Therefore, copper in the exposed portion is not oxidized.

In the conventional process, the curing is performed after etching the passivation film. It is therefore necessary to remove the polyimide altered layer 5a as the surface of the polyimide material 5 formed at the time of etching for the following reason. When the curing is performed in a state where the polyimide altered layer 5a resides, since a shrinkage of the polyimide altered layer 5a and that of the polyimide material in the area other than the polyimide altered layer 5a are different from each other, a wrinkle occurs in the surface of the polyimide material. In the first embodiment, however, the curing is performed before the polyimide altered layer 5a is formed. The process of removing the polyimide altered layer 5a is unnecessary, so that the manufacturing process can be simplified.

A second embodiment of the invention will now be described. In the first embodiment, the passivation layer 4 is one layer. In the second embodiment, the passivation layer has a two-layer structure.

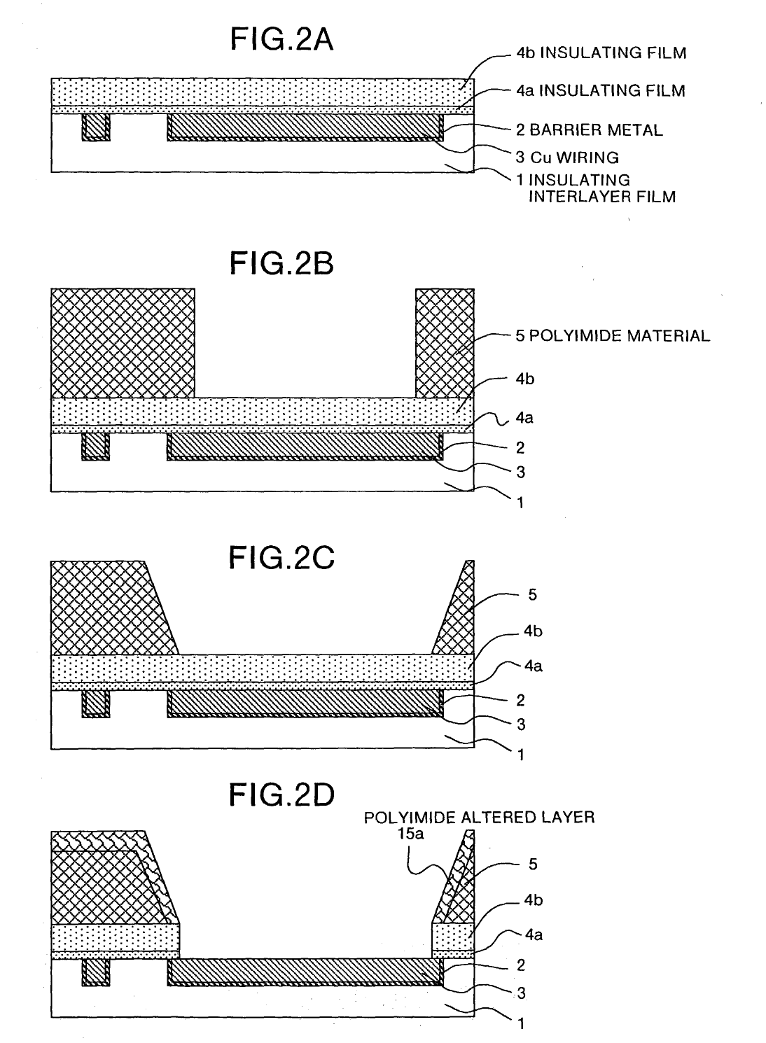

FIG. 2A to FIG. 2D are process drawings showing a method of fabricating a semiconductor device as the second embodiment of the invention. First, as shown in FIG. 2A, by using the Cu Damascene technique, the Cu wiring 3 having a planarized surface and obtained by burying copper in the insulating interlayer film 1 is formed. Further, on the planarized surface including the Cu wiring 3, insulating films 4a and 4b are sequentially deposited as a passivation film. The insulating film 4a is a silicon nitride film. As the insulating film 4a,a film having high adhesion to copper is selected to suppress diffusion-of copper around the border between the insulating film 4a and the insulating interlayer film 1. On the other hand, the insulating film 4b is a silicon nitride film and, as the insulating film 4b, a film having high moisture resistance and low dielectric constant is selected, so that the reliability can be improved and the capacity between the wiring and the insulating film can be reduced.

After that, as shown in FIG. 2B, the photosensitive polyimide material 5 is applied on the insulating film 4b, exposed, and developed, thereby forming an etching mask made of the polyimide material 5.

After curing the polyimide material 5 as shown in FIG. 2C, as shown in FIG. 2D, the insulating films 4b and 4a as the passivation film are etched by using the polyimide material 5 as an etching mask. At this time, the surface of the polyimide material 5 becomes a polyimide altered layer 15a.

Since the polyimide material 5 is cured (FIG. 2C) and, after that, the insulating layers 4b and 4a as a passivation film are etched, in the state where copper of the Cu wiring 3 is exposed and in an atmosphere where oxygen exists, the temperature does not rise above 100 degree centigrade. Therefore, copper in the exposed portion is not oxidized.

In the conventional process, the curing is performed after etching the passivation film. It is therefore necessary to remove the polyimide altered layer 15a as the surface of the polyimide material 5 formed at the time of etching for the following reason. When the curing is performed in a state where the polyimide altered layer 15a resides, since a shrinkage of the polyimide altered layer 15a and that of the polyimide material 5 in the area other than the polyimide altered layer 15a are different from each other, a wrinkle occurs in the surface of the polyimide material 5. In the second embodiment, however, the curing is performed before the polyimide altered layer 15a is formed. The process of removing the polyimide altered layer 15a is unnecessary, so that the manufacturing process can be simplified.

A third embodiment of the invention will now be described. Although the polyimide altered layer 5a is not removed in the foregoing first embodiment, in the third embodiment, the polyimide altered layer 5a is thinned as much as possible.

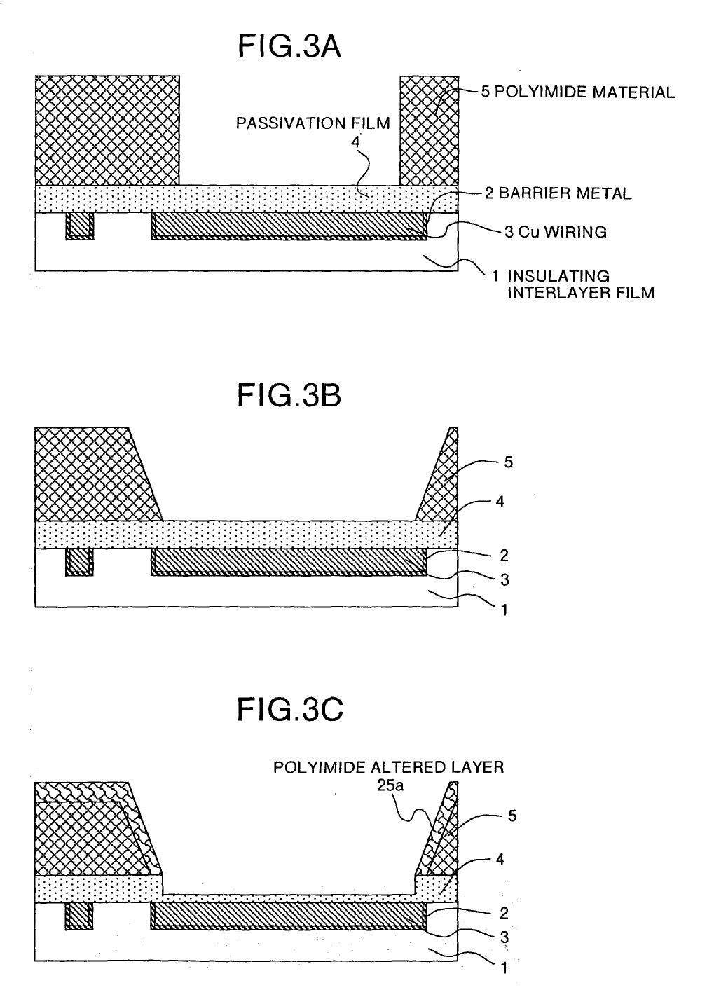

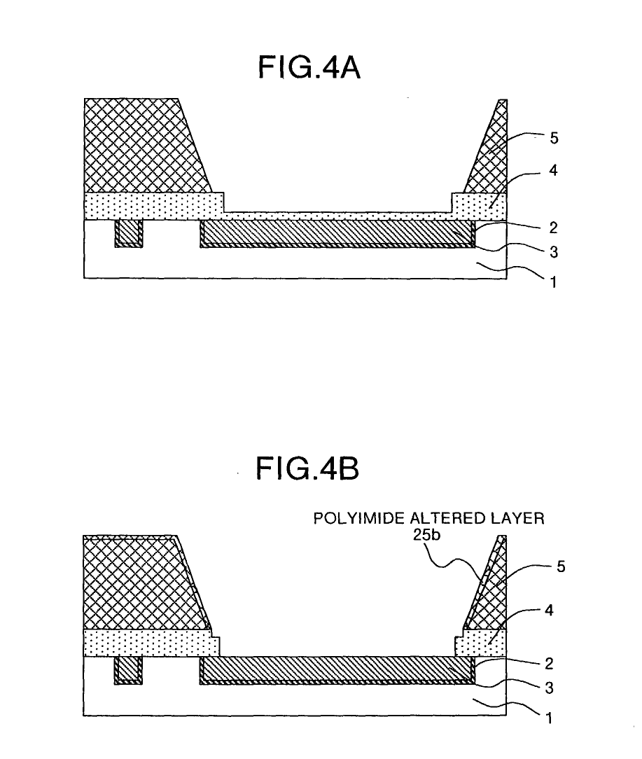

FIG. 3A to FIG. 3C and FIG. 4A and FIG. 4B are process drawings showing a method of fabricating a semiconductor device as the third embodiment of the invention. First, as shown in FIG. 3A, by using the Cu Damascene technique, the Cu wiring 3 having a planarized surface and obtained by burying copper in the insulating interlayer film 1 is formed. Further, the passivation film 4 is deposited on the planarized surface including the Cu wiring 3. After that, the photosensitive polyimide material 5 is applied on the passivation film 4, exposed, and developed, thereby forming an etching mask made of the polyimide material 5.

After curing the polyimide material 5 as shown in FIG. 3B, as shown in FIG. 3C, the passivation film 4 is etched by using the cured polyimide material 5 as an etching mask to a thickness of an extent that the Cu wiring 3 is not exposed. At the time of etching the passivation film 4, the surface of the polyimide material 5 becomes a polyimide altered layer 25a.

After that, the polyimide altered layer 25a is removed as shown in FIG. 4D, and the residual passivation layer 4 is further etched to thereby expose the Cu wiring 3 as shown in FIG. 4E. Although a polyimide altered layer 25b is formed again by the etching of this time, since the etching amount is small, the polyimide altered layer 25b is thinner than the polyimide altered layer 15a formed in the second embodiment. The occurrence of dusts at the time of forming bumps in an assembling process at a later time is therefore suppressed, and the occurrence of a defect is suppressed.

A fourth embodiment of the invention will now be described. In the fourth embodiment, the dimensional accuracy of the passivation film can be improved.

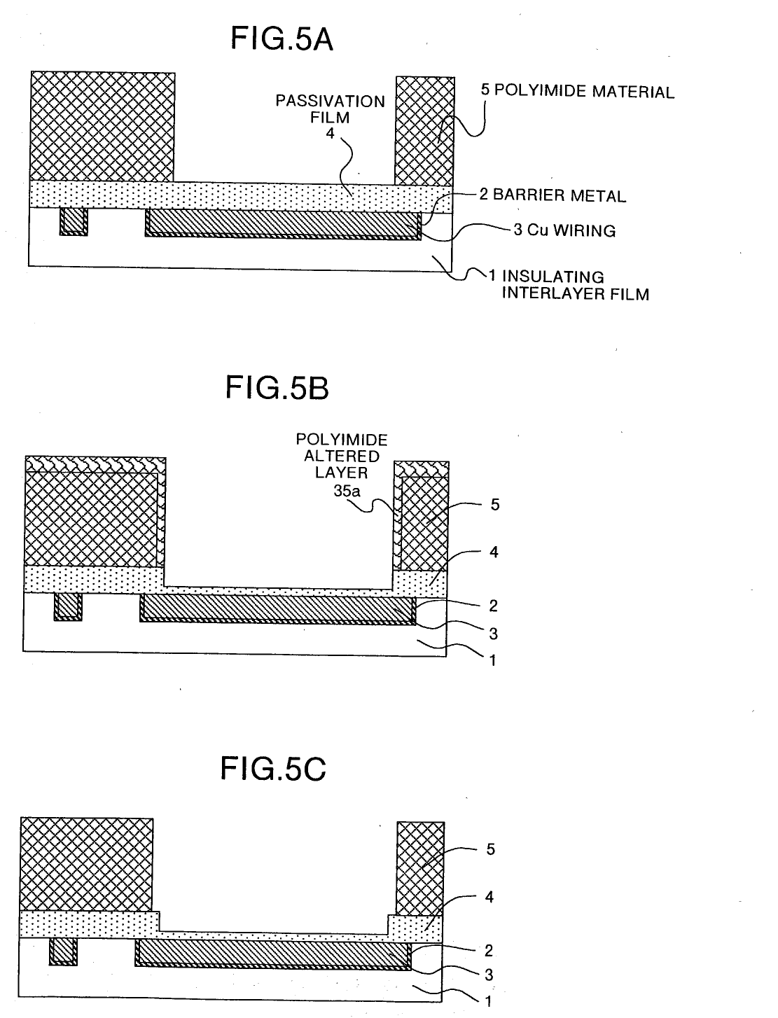

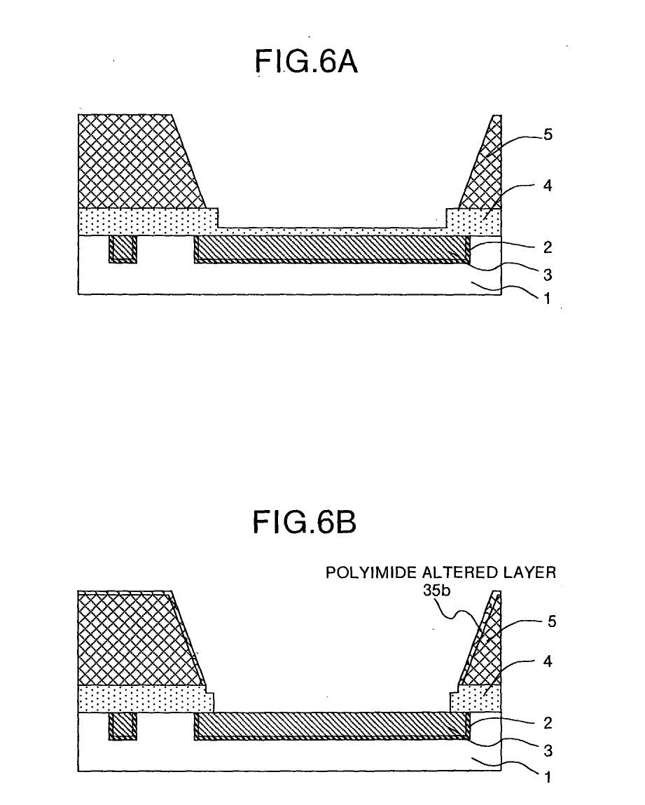

FIG. 5A to FIG. 5C and FIG. 6A and FIG. 6B are process drawings showing a method of fabricating a semiconductor device as the fourth embodiment of the invention. First, as shown in FIG. 5A, by using the Cu Damascene technique, the Cu wiring 3 having a planarized surface and obtained by burying copper in the insulating interlayer film 1 is formed. The passivation film 4 is deposited on the planarized surface including the Cu wiring 3. After that, the photosensitive polyimide material 5 is applied on the passivation film 4, exposed, and developed, thereby forming an etching mask made of the polyimide material 5.

Subsequently, as shown in FIG. 5B, the passivation film 4 is etched by using the polyimide material 5 as an etching mask to a thickness to an extent that the Cu wiring 3 is not exposed. At the time of etching the passivation film 4, a polyimide altered layer 35a is formed.

After that, the polyimide altered layer 35a is removed as shown in FIG. 5C and the polyimide material 5 is cured as shown in FIG. 6D. As shown in FIG. 6E, the residual passivation layer 4 is further etched to thereby expose the Cu wiring 3. Although a polyimide altered layer 35b is formed again by the etching at this time, since the etching amount is small, the polyimide altered layer 35b is thinner than the polyimide altered layer 15a formed in the second embodiment. The occurrence of dusts at the time of forming bumps in an assembling process at a later time is therefore suppressed, and the occurrence of a defect is suppressed.

The etched shape in the upper part of the passivation film 4 etched before the polyimide material 5 is cured (FIG. 6D) becomes the shape of an opening in the exposed portion of the Cu wiring 3. In this case, the dimension controllability is higher than that in the case of using the etching mask made of the shrunk polyimide material after the curing, so that the dimensional accuracy equivalent to that of the passivation od the conventional Al wiring can be obtained. Thus, it facilitates fine patterning on the passivation of a fuse portion or the like for the purpose of repairing a memory.

A fifth embodiment of the invention will now be described. Although the etching control is performed at the time of etching the passivation film 4 for the first time so as not to expose the Cu wiring 3 in the foregoing third and fourth embodiments, in the fifth embodiment, the etching control is carried out by using the insulating films 4a and 4b shown in the second embodiment.

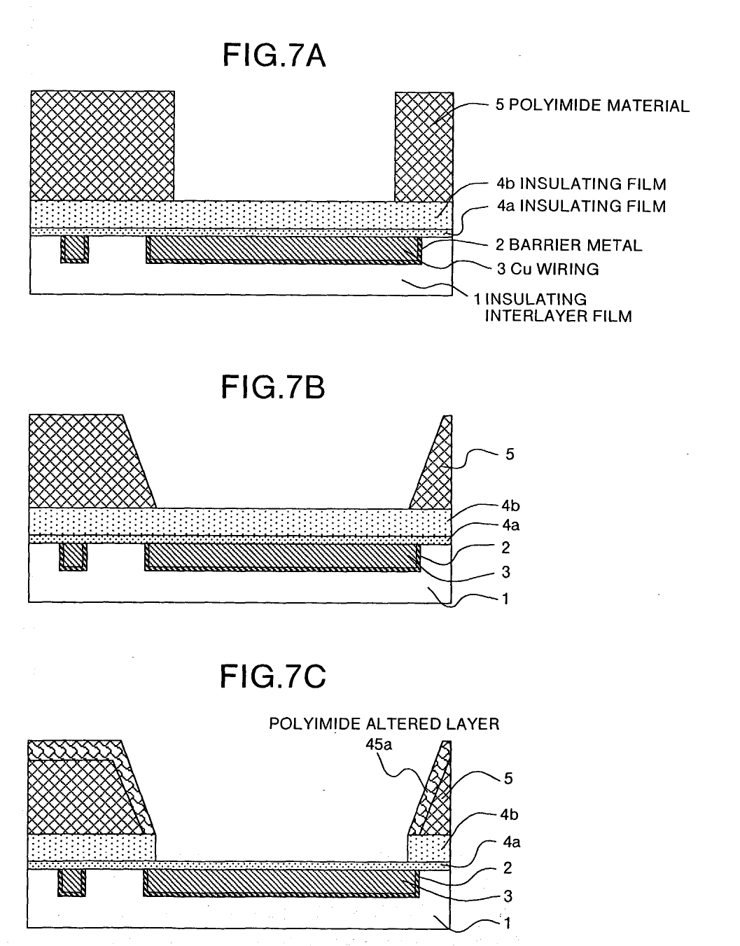

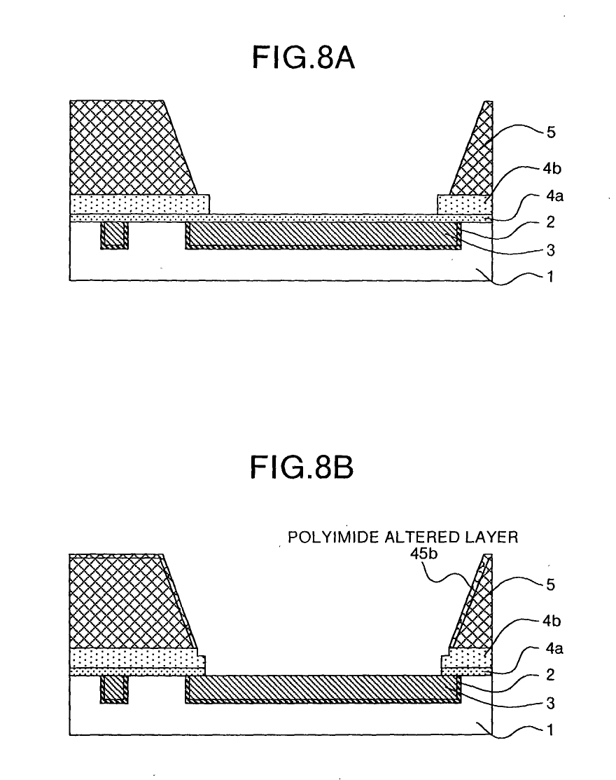

FIG. 7A to FIG. 7C and FIG. 8A and FIG. 8B are process drawings showing a method of fabricating a semiconductor device as the fifth embodiment of the invention. First, as shown in FIG. 7A, by using the Cu Damascene technique, the Cu wiring 3 having a planarized surface and obtained by burying copper in the insulating interlayer film 1 is formed. Further, on the planarized surface including the Cu wiring 3, the insulating films 4a and 4b are sequentially deposited as a passivation film. The insulating film 4a is a silicon nitride film, and as the insulating film 4a, a film having high adhesion to copper is selected to thereby suppress diffusion of copper around the border between the insulating film 4a and the insulating interlayer film 1. On the other hand, the insulating film 4b is a silicon nitride film and, as the insulating film 4b, a film having high moisture resistance and low dielectric constant is selected, so that the reliability can be improved and the capacity between the wiring and the insulating film can be reduced. The etch selectivity of the insulating film 4a and that of the insulating film 4b are different from each other. The photosensitive polyimide material 5 is applied on the insulating film 4b, exposed, and developed, thereby forming the etching mask made of the polyimide material 5.

After curing the polyimide material 5 as shown in FIG. 7B, as shown in FIG. 7C, the insulating film 4b is etched by using the cured polymide material 5 as an etching mask. At this time, the insulating film 4b is etched and the insulating film 4a is left so as not to expose the Cu wiring 3. In this case, the etch selectivity of the insulating film 4a and that of the insulating film 4b are different from each other, and the insulating film 4a functions as an etch stopper film.

Subsequently, the polyimide altered layer 45a is removed as shown in FIG. 8D, and the residue insulating film 4a is further etched to expose the Cu wiring 3 as shown in FIG. 8E. In this case, although the polyimide altered layer 45b is again formed by the etching, since the etching amount is small, the polyimide altered layer 45b is thinner than the polyimide altered layer 15a formed in the second embodiment. The occurrence of dusts at the time of forming bumps in an assembling process at a later time is therefore suppressed, and the occurrence of a defect is suppressed.

In the fifth embodiment, the passivation layer 4 is formed by the insulating films 4a and 4b, the insulating film 4a having the etch selectivity different from that of the insulating film 4b is provided on the Cu wiring 3 side to certainly prevent the Cu wiring 3 from being exposed by the etching of the first time (see FIG. 7C).

Although the fifth embodiment has been described as an embodiment corresponding to the third embodiment, the invention is not limited to this correspondence. For example, the passivation film 4 in the fourth embodiment may be formed as the insulating films 4a and 4b.

As described above, according to one aspect of this invention, the first insulating film covers the planarized surface including the copper wiring as the uppermost layer, and prevents diffusion of copper or has high adhesion to copper. The second insulating film having high moisture resistance or low dielectric constant is formed on the first insulating film. Therefore, the reliability can be improved and the capacity between the wiring and the insulating film can be reduced.

According to another aspect, a copper wiring is buried in an insulating interlayer film in the copper wiring burying step. In the first insulating film forming step, a first insulating film which prevents diffusion of copper or has high adhesion to copper is deposited on a planarized surface including the copper wiring as an uppermost layer. In the second insulating film forming step, a second insulating film having high moisture resistance or low dielectric constant is deposited on the first insulating film. In the etching mask forming step, an etching mask is formed by applying, exposing, and developing a photosensitive polyimide material on the second insulating film. In the curing step, the etching mask is cured. In the etching step, the second insulating film and the first insulating film are etched by using the etching mask cured in the curing step to expose the copper wiring as the uppermost layer. The diffusion of copper to the insulating film adjacent to the copper wiring is suppressed or adhesion of the insulating film to the copper wiring is increased by the first insulating film. Moisture resistance is enhanced or the dielectric is lowered by the second insulating film. Therefore, the reliability can be improved and the capacity between the wiring and the insulating film can be reduced.

According to still another aspect, in the copper wiring burying step, a copper wiring is buried in an insulating interlayer film. In a passivation film forming step, a passivation film is deposited on a planarized surface including the copper wiring as an uppermost layer. In the etching mask forming step, an etching mask is formed by applying, exposing, and developing a photosensitive polyimide material on the passivation film. In the curing step, the etching mask is cured. In the first etching step, the passivation film is etched to a predetermined thickness by using the etching mask cured in the first curing step. In the altered layer removing step, an altered layer generated on the surface of the etching mask in the first etching step is removed. In the second etching step, the passivation film having the predetermined thickness is etched to expose the copper wiring as the uppermost layer. In such a manner, the final thickness of the polyimide altered layer is made thin. Therefore, the occurrence of dusts at the time of forming bumps in an assembling process at a later time is suppressed, and the occurrence of a defect is suppressed so that it can be manufactured the semiconductor device having a high reliability.

According to still another aspect, in the copper wiring burying step, a copper wiring is buried in an insulating interlayer film. In the passivation film forming step, a passivation film is deposited on a planarized surface including the copper wiring as an uppermost layer. In the etching mask forming step, an etching mask is formed by applying, exposing, and developing a photosensitive polyimide material on the passivation film. In the first etching step, the passivation film is etched to a predetermined thickness by using the etching mask formed in the etching mask forming step. In the altered layer removing step, an altered layer generated on the surface of the etching mask in the first etching step is removed. In the curing step, the etching mask is cured. In the second etching step, the passivation film having the predetermined thickness is etched to expose the copper wiring as the uppermost layer. The shape in the upper part of the passivation film etched before the curing process becomes the shape of the opening of the copper wiring, thereby increasing the dimensional accuracy of the passivation of the copper wiring. Thus, it facilitates fine patterning on the passivation of a fuse portion or the like for the purpose of repairing a memory.

Furthermore, in the passivation film forming step, a first insulating film is deposited on a planarized surface including a copper wiring as an uppermost layer in the first insulating film forming step, and a second insulating film having an etch selectivity different from that of the first insulating film is deposited on the first insulating film in the second insulating film forming step. In the first etching step, the second insulating film formed in the second insulating film forming step is etched by using the etching mask formed in the etching mask forming step. In the second etching step, the second insulating film formed in the first insulating film forming step is etched. Therefore, it is can be prevented the penetration to Cu wiring securely at etching in the second etching step.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor device in which a passivation layer is formed on a copper wiring as an uppermost layer, wherein said passivation layer includes,
a first insulating film covering a planarized surface including said copper wiring as the uppermost layer, for preventing diffusion of copper or having high adhesion to copper; and
a second insulating film formed on said first insulating film, having high moisture resistance or low dielectric constant.

2. A method of fabricating a semiconductor device, comprising:
a copper wiring burying step of burying a copper wiring in an insulating interlayer film;
a first insulating film forming step of depositing a first insulating film which prevents diffusion of copper or has high adhesion to copper on a planarized surface including the copper wiring as an uppermost layer;
a second insulating film forming step of depositing a second insulating film having high moisture resistance or low dielectric constant on said first insulating film;
an etching mask forming step of forming an etching mask by applying, exposing, and developing a photosensitive polyimide material on said second insulating film;
a curing step of curing said etching mask; and
an etching step of etching said second insulating film and said first insulating film by using said etching mask cured in the curing step to expose said copper wiring as the uppermost layer.

3. A method of fabricating a semiconductor device, comprising:
a copper wiring burying step of burying a copper wiring in an insulating interlayer film;
a passivation film forming step of depositing a passivation film on a planarized surface including the copper wiring as an uppermost layer;
an etching mask forming step of forming an etching mask by applying, exposing, and developing a photosensitive polyimide material on said passivation film;
a first etching step of etching said passivation film to a predetermined thickness by using said etching mask formed in the etching mask forming step;
an altered layer removing step of removing an altered layer generated on the surface of the etching mask in the first etching step;
a curing step of curing said etching mask; and
a second etching step of etching said passivation film having the predetermined thickness to expose the copper wiring as the uppermost layer.

4. The method of fabricating a semiconductor device according to claim 3, wherein the passivation film forming step includes,
a first insulating film forming step of depositing a first insulating film on a planarized surface including a copper wiring as an uppermost layer; and
a second insulating film forming step of depositing a second insulating film having an etch selectivity different from that of said first insulating film on said first insulating film, and
wherein in the first etching step, said second insulating film formed in said second insulating film forming step is etched by using the etching mask formed in the etching mask forming step, and
in the second etching step, said second insulating film formed in the first insulating film forming step is etched.
